(19) United States
(12) Patent Application Publication
(10) Pub. No.: US 2010/0205493 A1
(43) Pub. Date: Aug. 12, 2010

(54) SEMICONDUCTOR INTEGRATED CIRCUIT, METHOD OF TESTING SEMICONDUCTOR INTEGRATED CIRCUIT, AND METHOD OF DESIGNING SEMICONDUCTOR INTEGRATED CIRCUIT

(75) Inventor: Kuninobu FUJII, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/700,925

(22) Filed: Feb. 5, 2010

(30) Foreign Application Priority Data
Feb. 9, 2009 (JP) 2009-026949

(51) Int. Cl. G01R 31/3177; G06F 11/25

(52) U.S. Cl. 714/729; 714/724; 714/E11.155

(57) ABSTRACT

A semiconductor integrated circuit includes first and second scan storage elements forming a scan chain, and first and second logic circuits connected to inputs of the first and second scan storage elements respectively, wherein the first logic circuit includes a first logic path and a second logic path to an input of the first scan storage element, the first logic path becomes active in a normal state and has a delay difference larger than or equal to a predetermined range with respect to a third logic path possessed by the second logic circuit, the third logic path extending to an input of the second scan storage element, and the second logic path becomes active during a scan test and has a delay difference within a predetermined range with respect to the third logic path.

### INCORPORATION BY REFERENCE

This application is based upon and claims the benefit of priority from Japanese patent application No. 2009-026949, filed on Feb. 9, 2009, the disclosure of which is incorporated herein in its entirety by reference.

### BACKGROUND

1. Field of the Invention

The present invention relates to a semiconductor integrated circuit, a method of testing a semiconductor integrated circuit, and a method of designing a semiconductor integrated circuit.

2. Description of Related Art

For semiconductor integrated circuits, a function test to test whether or not they perform desired functions and a delay test to test whether or not they operate in desired operating frequencies are carried out. Testing techniques using a scan test circuit have been adopted as one of function and delay testing methods for such semiconductor integrated circuits. A function and delay test using a scan test circuit in related art is briefly explained hereinafter with reference to FIGS. 13 to 15.

As shown in FIG. 13, a scan test circuit is incorporated into a semiconductor integrated circuit 1 that includes combinational circuits (logic circuits), sequential circuits (flip-flops), and the likes to implement desired functions. This scan test circuit replaces part of or the entire sequential circuits of the semiconductor integrated circuit 1 with scan storage elements. Note that in FIG. 13, only three scan storage elements are illustrated for simplifying the drawing. In the scan storage elements 11 to 13, the input of each scan storage element is connected to the output of the preceding scan storage element.

FIG. 14 shows a configuration example of each of the scan storage elements 11 to 13. As shown in FIG. 14, each of the scan storage elements 11 to 13 includes a flip-flop FF1 and a selector MUX1. Further, each of the scan storage elements 11 to 13 includes a data input terminal Din, a data output terminal Dout, a scan-in terminal Sin, a scan enable terminal SEN, and a clock terminal CLK.

Output data from the preceding logic circuit is input to the data input terminal Din. Scan data from the preceding scan storage element is input to the scan-in terminal Sin. A scan enable signal is input to the scan enable terminal SEN. A clock signal clk is input to the clock terminal CLK. Output data from the flip-flop FF1 is output from the data output terminal Dout.

The selector MUX1 outputs data input from either data input terminal Din or the scan-in terminal Sin to the flip-flop FF1 according to the set value of the scan enable signal scan_en that is set in the scan-in enable terminal SEN. The flip-flop FF1 latches data input to an input terminal D, stores and retains the data, and outputs the data from the output terminal Q according to a clock signal input to the clock terminal CLK.

In the semiconductor integrated circuit 1, one scan chain is formed from a scan data input terminal 31 to a scan data output terminal 35 through the scan storage elements 11 to 13. Note that in the semiconductor integrated circuit 1 shown in FIG. 13, although only the scan storage elements 11 to 13 are illustrated for simplifying the drawing, it may includes a plurality of other scan storage elements in front of the scan storage element 11 and behind the scan storage element 13. This scan test circuit having the scan chain can be switched between a shift mode in which the above-described scan is activated and a scan mode in which sequential circuits (flip-flops FF1 of respective scan elements) take in the outputs of the logic circuits 21 and 22 according to the value of the scan enable signal scan_en. Note that the scan mode is also used as the normal operating mode of the semiconductor integrated circuit 1.

Operations of the scan test circuit of the semiconductor integrated circuit 1 are briefly explained hereinafter. FIG. 15 shows a timing chart of the scan test circuit of the semiconductor integrated circuit 1. Firstly, the scan enable signal scan_en is kept at a High level until a time t1. The scan test circuit is in a shift mode during the period in which the scan enable signal scan_en is at the High level. In the semiconductor integrated circuit 1 in the shift mode, the scan storage elements 11 to 13 are initialized with scan data that are input from the scan-in terminal 31 in synchronization with a rising edge of the clock signal ca.

Then, the scan enable signal scan_en is brought to a Low level from the time t1 to t4. The scan test circuit is in a scan mode during the period in which the scan enable signal scan_en is at the Low level. In the semiconductor integrated circuit 1 in the scan mode, a clock signal clk having a desired pulse cycle is input to the clock terminal 34 at times t2 and t3. As a result of these actions, operation results of the logic circuits 21 and 22 according to the initial values are stored and retained in the scan storage elements 11 to 13.

Finally, the scan enable signal scan_en is brought to a High level from the time t4. Consequently, it enters the shift mode again, in which the clock signal clk is applied and an operation result is taken out from the scan data output terminal 35. A function test and a delay test of the semiconductor integrated circuit 1 are carried out by comparing this operation result that was externally taken out with expected values that were obtained in advance. Further, Japanese Unexamined Patent Application Publication No. 2007-178255 (Patent document 1) and the like in prior art disclose a technique to improve the reliability of diagnoses by such scan tests.

### SUMMARY

In recent years, as miniaturization in the manufacturing process of semiconductor integrated circuits such as LSIs has advanced, their circuit scale has increased and the increase in their packing density has advanced even further. Therefore, the degree of difficulty in detecting faulty parts has also increased. Further, since the increase in the processing speed has also advanced, specifying parts that cause delay faults has become very difficult. In semiconductor integrated circuits having such a high packing density and a high processing speed, specifying faulty parts has become very difficult even when the above-described scan test is carried out. For example, a problem described below is conceivable.

Firstly, FIGS. 16 and 17 show schematic diagrams to show a relation between delay times of the logic circuits 21 and 22. FIG. 16 shows a case where the circuit is properly configured, and FIG. 17 shows a case where the semiconductor integrated circuit 1 has a defect in its circuit configuration. As shown in FIG. 16, assume that the logic circuit 21 has a delay value “5”, and the logic circuit 22 has a delay value “10”. Note that the term “delay value” means a delay time in regard to the input/output response of a logic circuit. Assume that as the numerical value of this delay value becomes larger, the delay time in regard to the input/output response of the logic circuit becomes longer.

As shown in FIG. 16, the delay value of the logic circuit 22 is larger than that of the logic circuit 21. Therefore, the pulse cycle of the clock signal clk that is input to the scan storage elements 11 to 13 during the scan mode is set in accordance with the delay value of the logic circuit 22. However, even if the logic circuit 21 has some defect and thereby has an abnormal delay value of “8” instead of the desired delay value of “5” as shown in FIG. 17, the scan test cannot detect the defect and it is thereby overlooked. There is a possibility that this defect arises when the operating environment is changed due to the temperature change or the like, for example, and the delay value of the logic circuit 21 thereby becomes larger than that of the logic circuit 22, or when a similar situation occurs. If the defect arises in this manner, it poses a risk that the semiconductor integrated circuit may malfunction.

Similarly, in the above-described circuit of Patent document 1, if there is a defect similar to the above-described defect in logic circuits between the respective sequential circuits (flip-flops), that defect cannot be detected due to the effect of the logic circuit having a larger delay value. Therefore, a configuration, a testing method, and a design method for a scan test circuit capable of detecting such a hidden defect have been sought in semiconductor integrated circuits.

A first exemplary aspect of an embodiment of the present invention is a semiconductor integrated circuit including: first and second scan storage elements forming a scan chain; and first and second logic circuits connected to inputs of the first and second scan storage elements respectively, wherein the first logic circuit includes a first logic path and a second logic path to an input of the first scan storage element, the first logic path becomes active in a normal state and has a delay difference larger than or equal to a predetermined range with respect to a third logic path possessed by the second logic circuit, the third logic path extending to an input of the second scan storage element, and the second logic path becomes active during a scan test and has a delay difference within a predetermined range with respect to the third logic path.

In a semiconductor integrated circuit in accordance an exemplary aspect of the present invention, a delay difference between the second and third logic paths of the first and second logic circuits connected to the respective scan storage elements falls within a predetermined range. Therefore, if the first logic circuit has a defect, it can be detected as an error during a scan test.

Another exemplary aspect of an embodiment of the present invention is a method of designing a semiconductor integrated circuit by using a computer, the semiconductor integrated circuit including a plurality of logic circuits each of which receives an output signal from a flip-flop connected in a preceding stage and outputs its operation result to a flip-flop in a subsequent stage, the method including: creating a net list containing circuit information of first and second logic circuits among the plurality of the logic circuits, a first flip-flop that receives an output of the first logic circuit, and a second flip-flop that receives an output of the second logic circuit; and referring to the net list and a delay information report containing information of delays of the first and second logic circuits, and when a delay difference between the first and second logic circuits falls within a predetermined range, connecting the first and second flip-flops in a scan-chain connection.

Another exemplary aspect of an embodiment of the present invention is a method of designing a semiconductor integrated circuit by using a computer, the semiconductor integrated circuit including a plurality of logic circuits each of which receives an output signal from a flip-flop connected in a preceding stage and outputs its operation result to a flip-flop in a subsequent stage, the method including: creating a net list containing circuit information of first and second logic circuits among the plurality of the logic circuits, a first flip-flop that receives an output of the first logic circuit, and a second flip-flop that receives an output of the second logic circuit; configuring at least one of the first and second logic circuits such that a division of a logic circuit or an addition of a delay circuit is possible in order to bring a delay difference between the first and second logic circuits within a predetermined range during a scan test by referring to the net list and a delay information report containing information of delays of the first and second logic circuits; and connecting the first and second flip-flops in a scan-chain connection.

Another exemplary aspect of an embodiment of the present invention is a method of testing a semiconductor integrated circuit, the semiconductor integrated circuit including: first and second scan storage elements forming a scan chain; and first and second logic circuits connected to inputs of the first and second scan storage elements respectively, wherein the first logic circuit includes a first logic path and a second logic path to an input of the first scan storage element, and the second logic circuit includes a third logic path to an input of the second scan storage element, the third logic path having a delay difference that is larger than or equal to a predetermined range with respect to the first logic path and within a predetermined range with respect to the second logic path, and wherein the semiconductor integrated circuit is operated with the first logic path in a normal state and operated with second logic path during a scan test.

In a semiconductor integrated circuit in accordance with an exemplary aspect of the present invention, it is possible to detect a defect of a combinational circuit that is hidden in traditional scan tests.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a configuration of a semiconductor integrated circuit in accordance with a first exemplary embodiment of the present invention;

FIG. 2 is a schematic diagram for explaining advantageous effects of a semiconductor integrated circuit in accordance with a first exemplary embodiment of the present invention;

FIG. 3 is another configuration example of a semiconductor integrated circuit in accordance with a first exemplary embodiment of the present invention;

FIG. 4 is a configuration of a semiconductor integrated circuit in accordance with a second exemplary embodiment of the present invention;

FIG. 5 is a schematic diagram for explaining advantageous effects of a semiconductor integrated circuit in accordance with a second exemplary embodiment of the present invention;

FIG. 6 is a configuration of a semiconductor integrated circuit in accordance with a third exemplary embodiment of the present invention;

FIG. 7 is a configuration of a semiconductor integrated circuit in related art;

FIG. 8 is a schematic diagram for explaining advantageous effects of a semiconductor integrated circuit in accordance with a third exemplary embodiment of the present invention;

FIG. 9 is another configuration example of a semiconductor integrated circuit in accordance with a third exemplary embodiment of the present invention;

FIG. 10 is a schematic diagram for explaining a method of designing a semiconductor integrated circuit in accordance with a fourth exemplary embodiment of the present invention;

FIG. 11 is a flowchart of a method of designing a semiconductor integrated circuit in accordance with a fourth exemplary embodiment of the present invention;

FIG. 12 is a configuration of a semiconductor integrated circuit in accordance with another exemplary embodiment of the present invention;

FIG. 13 is a configuration of a semiconductor integrated circuit in related art;

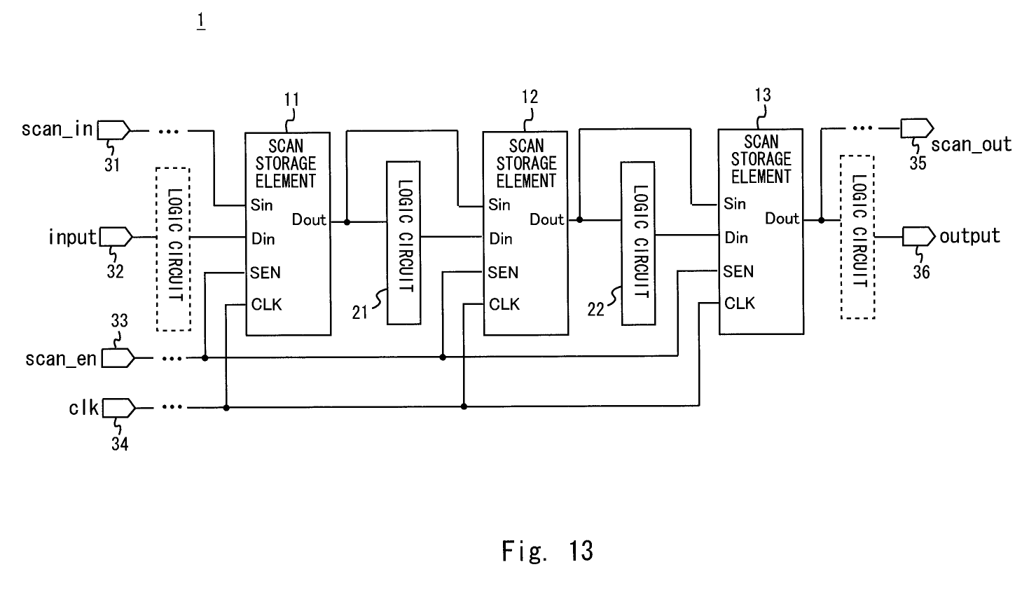

FIG. 14 is a configuration of a scan storage element;

FIG. 15 is a timing chart of a typical scan test;

FIG. 16 is a schematic diagram for explaining a problem of a semiconductor integrated circuit in related art; and

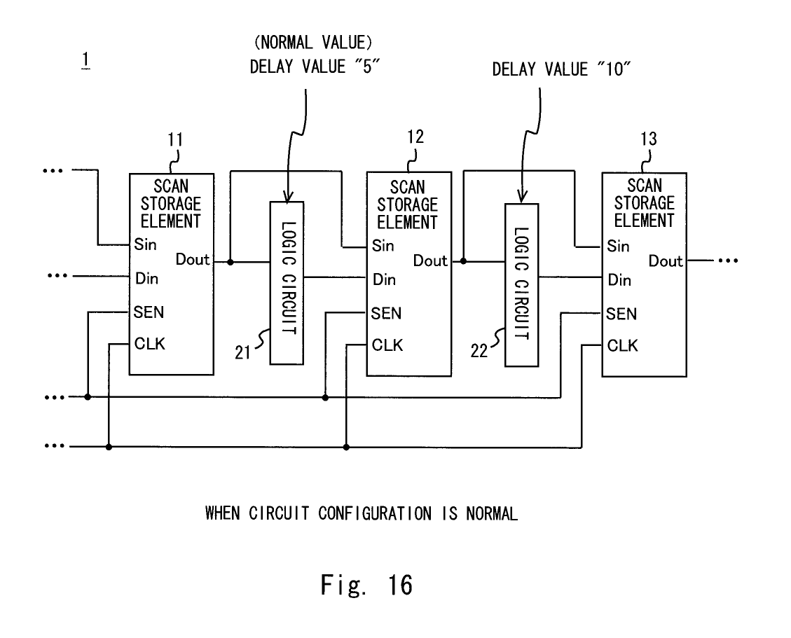

FIG. 17 is a schematic diagram for explaining a problem of a semiconductor integrated circuit in related art.

### DETAILED DESCRIPTION OF THE EXEMPLARY EMBODIMENTS

### First Exemplary Embodiment

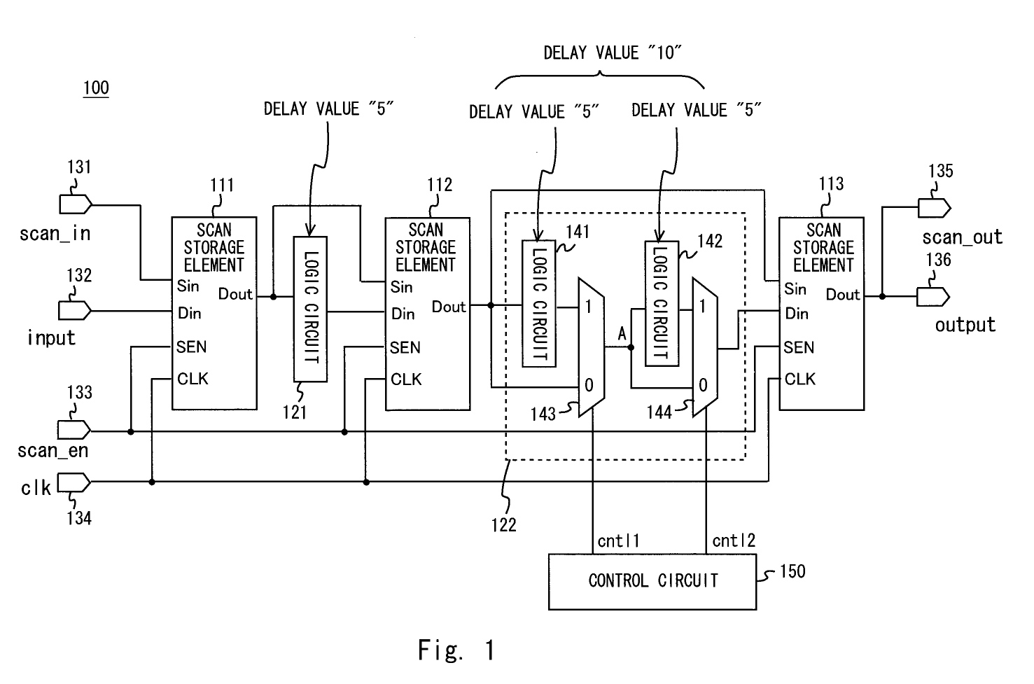

A first specific exemplary embodiment to which the present invention is applied is explained hereinafter with reference to the drawings. FIG. 1 shows an example of a configuration of a semiconductor integrated circuit 100 in accordance with this exemplary embodiment of the present invention. Assume that in this first exemplary embodiment, a scan test circuit is formed from combinational circuits (logic circuits) and sequential circuits such as flip-flops that are used to implement desired functions. Assume also that the semiconductor integrated circuit 100 illustrated in the drawings represents a configuration in a scan test circuit.

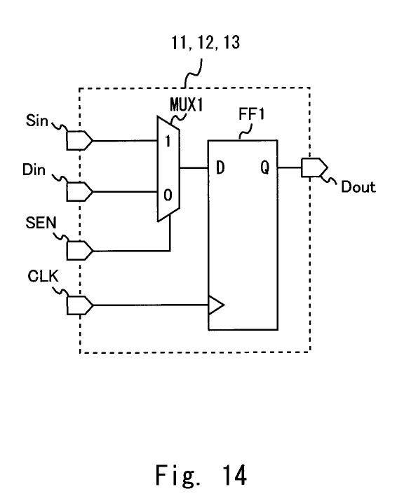

As shown in FIG. 1, the semiconductor integrated circuit 100 includes scan storage elements 111 to 113, logic circuits 121 and 122, and a control circuit 150. Further, the semiconductor integrated circuit 100 also includes a scan data input terminal 131, a data input terminal 132, a scan enable signal input terminal 133, a clock signal input terminal 134, a scan data output terminal 135, and a data output terminal 136. Note that each of the scan storage elements 111 to 113 has a similar configuration to that of the scan storage elements 11 to 13 shown in FIG. 14. Therefore, since their configuration and operations were already explained above, their explanation is omitted here. Further, this first exemplary embodiment is illustrated with only three scan storage elements for simplifying the drawings.

In the scan storage elements 111 to 113, the input of each scan storage element is connected to the output of the preceding scan storage element. That is, the scan storage elements 111 to 113 form a serially-connected shift register. Scan data is input from the scan data input terminal 131 to the scan storage element 111 in the first stage of this shift register. The scan storage element 113 in the last stage outputs its output to the scan data output terminal 135. In this way, one scan chain is formed from the scan data input terminal 131, the scan storage elements 111 to 113, and the scan data output terminal 135 in the semiconductor integrated circuit 100.

The clock signal input terminal 134 receives a clock signal clk that is used to operate the semiconductor integrated circuit 100. Further, it receives a test clock signal clk during a scan test. The scan enable signal input terminal 133 receives a scan enable signal scan_en. The scan enable signal scan_en is kept at a Low level when the semiconductor integrated circuit 100 is in a normal operating state. The scan data input terminal 131 receives scan data to be set in the scan storage elements in a scan test. The scan data output terminal 135 outputs a test result retained in the scan storage elements after a scan test. The data input terminal 132 receives an input data signal “input” that is used when the semiconductor integrated circuit 100 in a normal operating state. The data output terminal 136 outputs an output data signal “output” of the combinational circuits (logic circuits 121 and 122) according to the input data signal “input” when the semiconductor integrated circuit 100 is in a normal operating state. Note that a common terminal may be used as both the scan data output terminal 135 and the data output terminal 136 if there is no logic circuit behind the scan storage element 113.

Each of the logic circuits 121 and 122 is composed of, for example, a plurality of logic operation elements such as an AND circuit and an inverter circuit. Further, each of the logic circuit 121 and 122 outputs a result of a predetermined logic operation for an input data signal to a scan storage element in the subsequent stage. The logic circuit 121 receives an input data signal from the Dout terminal of the scan storage element 111, and outputs a logic operation result for the input to the Din terminal of the scan storage element 112. The logic circuit 122 receives an input data signal from the Dout terminal of the scan storage element 112, and outputs a logic operation result for the input to the Din terminal of the scan storage element 113. Assume that in this first exemplary embodiment, the logic circuit 121 has a delay value “5” and the logic circuit 122 has a delay value “10”. Note that the term “delay value” means a delay time in regard to the input/output response of a logic circuit as described above. Assume that as the numerical value of this delay value becomes larger, the delay time in regard to the input/output response of the logic circuit becomes longer. Therefore, the delay time of the logic circuit 122 is about twice that of the logic circuit 121 in this first exemplary embodiment.

The logic circuit 122 includes logic circuits 141 and 142, and selection circuits 143 and 144. Assume that when an operation result of the logic circuit 141 is input to the logic circuit 142, its output operation result becomes the same as the output operation result of the logic circuit 122. That is, the logic circuits 141 and 142 are obtained by dividing a plurality of logic operation elements constituting the logic circuit 122 at a certain node(s) and unitizing each of the front and rear sections divided at the node(s).

The logic circuit 141 receives an input data signal from the Dout terminal of the scan storage element 112, and outputs a logic operation result for the input to one of the input terminals of the selection circuit 144. Further, the logic circuit 141 is configured so as to have the same delay value as that of the logic circuit 121, i.e., a delay value “5”.

One of the input terminals of the selection circuit 143 is connected to the output of the logic circuit 141 and the other input terminal is connected to the Dout terminal of the scan storage element 112. Further, the output terminal of the selection circuit 143 is connected to a node A. Further, a control signal cntl1 from the control circuit 150 is input to the control terminal of the selection circuit 143. It selects a data signal input to either the one input terminal or the other input terminal according to this control signal cntl1, and outputs the selected data signal from the output terminal. More specifically, when the control signal cntl1 is at a High level, it outputs a data signal input to the one input terminal from the output terminal. On the other hand, when the control signal cntl1 is at a Low level, it outputs a data signal input to the other input terminal from the output terminal.

The logic circuit 142 receives a data signal from the node A, i.e., from the output terminal of the selection circuit 143, and outputs a logic operation result for the input to one of the input terminals of the selection circuit 144. Further, the logic circuit 142 is configured so as to have the same delay value as that of the logic circuit 121, i.e., a delay value “5”.

One of the input terminals of the selection circuit 144 is connected to the output of the logic circuit 142 and the other input terminal is connected to the node A. Further, the output terminal of the selection circuit 144 is connected to the Din terminal of the scan storage element 113. Further, a control signal cntl2 from the control circuit 150 is input to the control terminal of the selection circuit 144. It selects a data signal input to either the one input terminal or the other input terminal according to this control signal cntl2, and outputs the selected data signal from the output terminal. More specifically, when the control signal cntl2 is at a High level, it outputs a data signal input to the one input terminal from the output terminal. On the other hand, when the control signal cntl2 is at a Low level, it outputs a data signal input to the other input terminal from the output terminal.

In this manner, the logic circuit 122 includes therein the logic circuits 141 and 142, each of which has a delay value “5” obtained by dividing the delay value “10” of the logic circuit 122. Further, the selection circuits 143 and 144 operate according to the control signals cntl1 and cntl2, respectively, supplied from the control circuit 150. Therefore, either one of the output operation results of the logic circuits 141 and 142 is transmitted to the scan storage element 113 in the subsequent stage according to the control signals of the control circuit 150. Accordingly, the delay value of the circuit disposed between the scan storage elements 111 and 112 (second logic circuit) becomes roughly equal to the delay value of the circuit disposed between the scan storage elements 112 and 113 (first logic circuit).

Note that in the example shown in FIG. 1, a path that extends from the Dout terminal of the scan storage element 112, passes through the logic circuits 141 and 142, and connects to the Din terminal of the scan storage element 113 is defined as a first logic path. Further, a path that passes through either one of the logic circuit 141 or 142 and connects to the Din terminal of the scan storage element 113 is defined as a second logic path. Furthermore, a path that extends from the Dout terminal of the scan storage element 111, passes through the logic circuit 121, and connects to the Din terminal of the scan storage element 112 is defined as a third logic path.

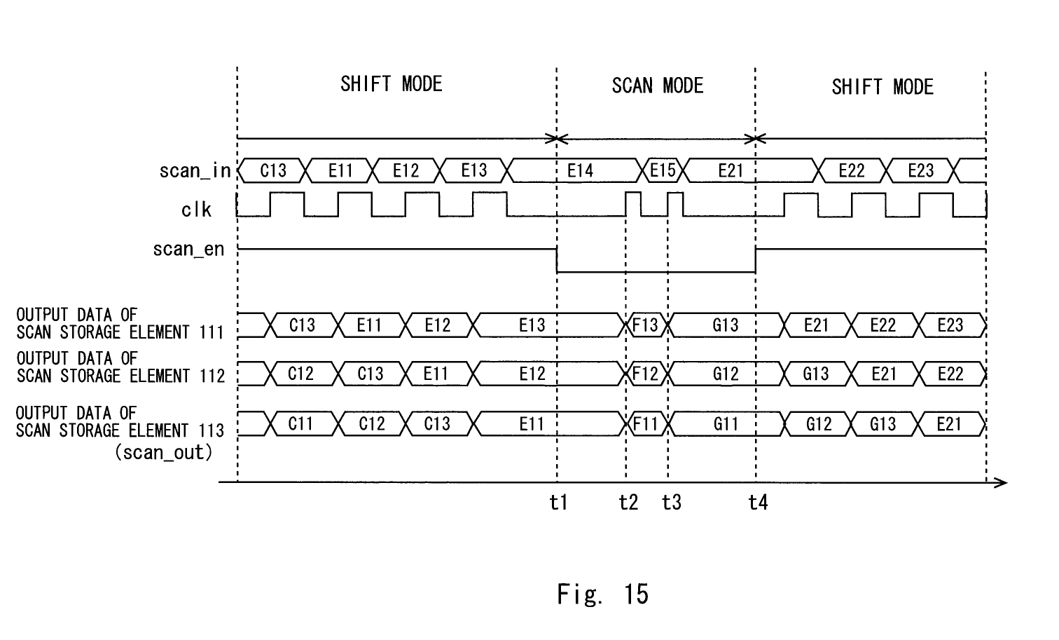

Next, operations of the above-described semiconductor integrated circuit 100 are explained hereinafter. Note that since fundamental scan test operations were already explained above with reference to FIG. 15 and the like, their explanation is omitted here. Operations of the logic circuit 122 during a scan test, which is a characteristic part of this first exemplary embodiment, are explained hereinafter.

Firstly, the control signal cntl1 output from the control circuit 150 is brought to a Low level, and the control signal cntl2 is brought to a High level. In this state (hereinafter referred to as “first state”), only the operation result of the logic circuit 142 is reflected on a data signal that is input to the input terminal Din of the scan storage element 113 in the scan mode. That is, the path that passes through only the logic circuit 142 is selected among the paths between the output terminal Dout of the scan storage element 112 and the input terminal Din of the scan storage element 113 by the control signals cntl1 and cntl2. Therefore, the delay values of the logic circuit 121 and 122 both become “5”. Accordingly, the clock signal clk for use in a scan mode of a scan test can be used while its pulse cycle is set to a delay value “5”, which is shorter than the delay value “10”.

Next, the control signal cntl1 output from the control circuit 150 is brought to a High level, and the control signal cntl2 is brought to a Low level. In this state, only the operation result of the logic circuit 141 is reflected on a data signal that is input to the input terminal Din of the scan storage element 113 in the scan mode. That is, the path that passes through only the logic circuit 141 is selected among the paths between the output terminal Dout of the scan storage element 112 and the input terminal Din of the scan storage element 113 by the control signals cntl1 and cntl2. In this state (hereinafter referred to as “second state”), the delay values of the logic circuit 121 and 122 both become “5”. Therefore, the clock signal clk for use in a scan mode of a scan test can be used while its pulse cycle is set to a delay value “5”.

Note that when the semiconductor integrated circuit 100 is in a normal operating state, the control signals cntl1 and cntl2 output from the control circuit 150 are both brought to a High level. In this case, the path that passes through both the logic circuits 141 and 142 is selected among the paths between the output terminal Dout of the scan storage element 112 and the input terminal Din of the scan storage element 113. Therefore, a data signal that is input to the input terminal Din of the scan storage element 113 becomes an operation result by both the logic circuits 141 and 142, i.e., an operation result of the logic circuit 122. Accordingly, even though the semiconductor integrated circuit 100 has a configuration in accordance with this first exemplary embodiment, it has no effect on operations in the normal operating state.

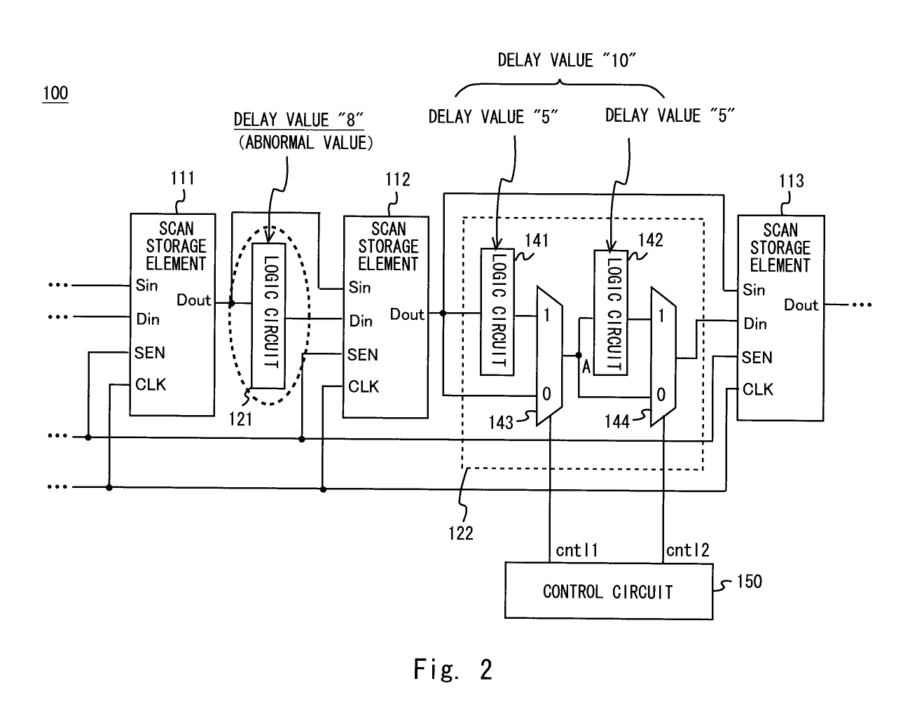

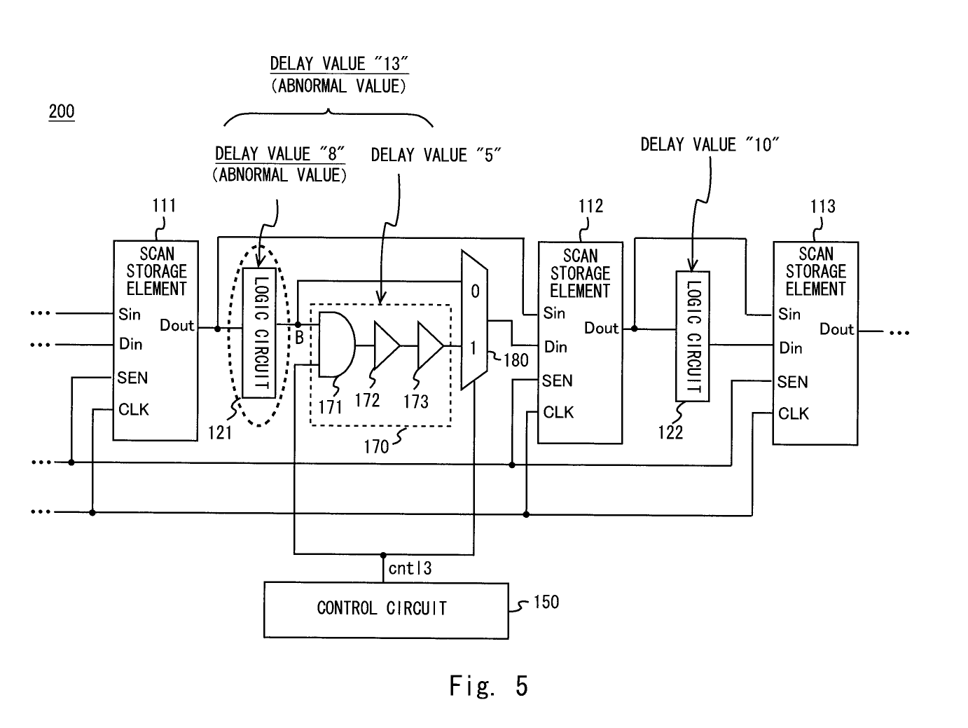

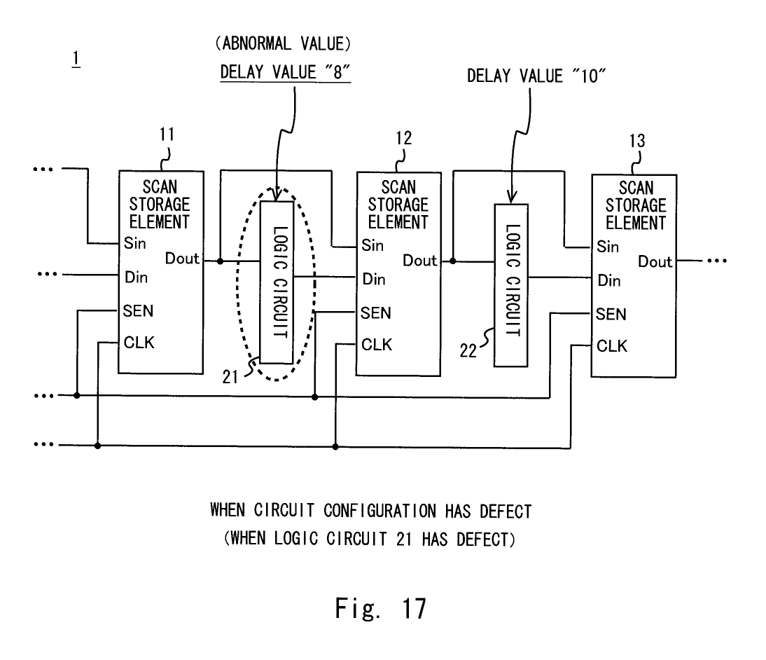

Note that as explained with FIG. 17, in the semiconductor integrated circuit 1 in related art, a defect in the logic circuit 21 cannot be detected due to the effect of the delay value of the logic circuit 22, which is the critical path, even if a scan test is carried out. By contrast, in the semiconductor integrated circuit 100 in accordance with this first exemplary embodiment of the present invention, the logic circuit 122, which is the critical path, is divided into the logic circuits 141 and 142 such that they have the same delay value “5” as that of the logic circuit 121 as shown in FIG. 5. Then, during the scan test, each test is carried out with a path that passes through only the respective one of the logic circuits 141 and 142. The pulse cycle of the clock signal clk for use in a scan mode for this case is set in accordance with the delay value “5”. In this manner, as shown in a schematic diagram of FIG. 2, if the logic circuit 121 has some defect and thereby has an abnormal delay value of “8” instead of the normal delay value of “5”, a result indicating that the data measured by the scan test is different from the expected values is obtained. Therefore, it becomes possible to detect a defect in the logic circuit 121 that cannot be detected in the circuit configuration of the semiconductor integrated circuit 1.

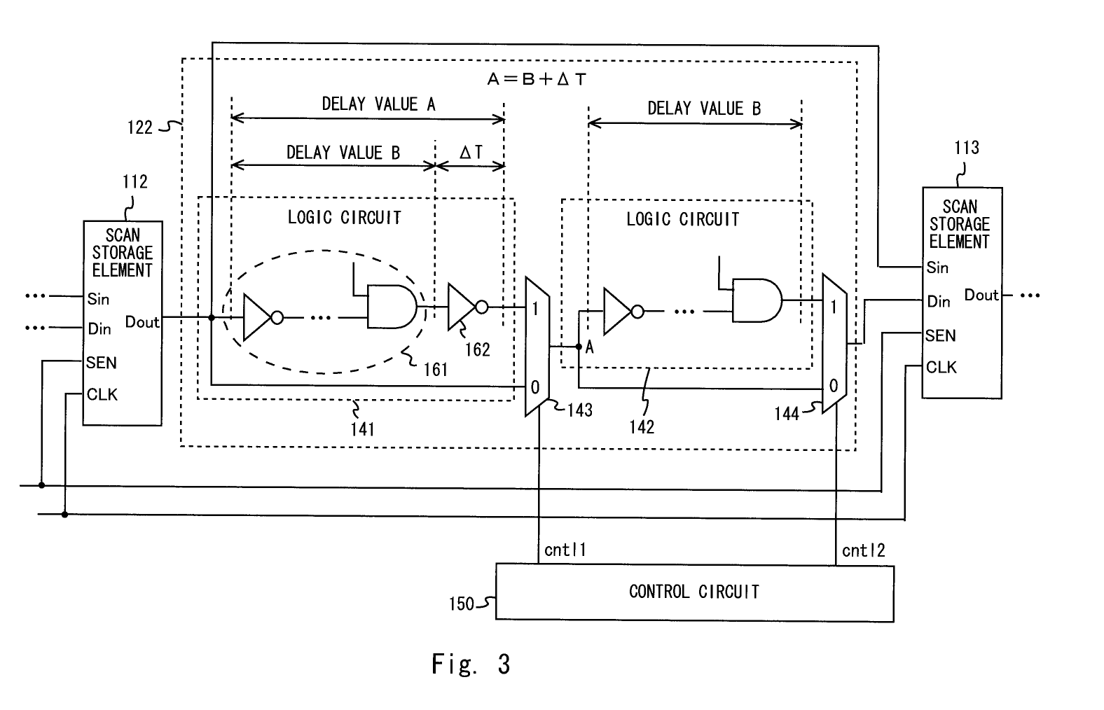

Further, in the above explanation, a configuration in which the logic circuit 122 having a delay value “10” is divided into the logic circuits 141 and 142 each having a delay value “5”, which is an exact half of the delay value of the logic circuit 122. However, depending on the configuration of a plurality of logic operation elements within a logic circuit 122, it is conceivable that the logic circuit 122 cannot be desirably divided into logic circuits 141 and 142 each having the same delay value. For example, assume a case where a logic circuit 122 is divided into logic circuits 141 and 142 having different delay values “A” and “B” as shown in FIG. 3, Assume also that the delay values “A” and “B” have a relation A>B. However, the delay value “A” of the logic circuit 141 is set to a value that is obtained by adding a predetermined delay value “ΔT” to the delay value “B”. That is, as shown in FIG. 3, the logic circuit 141 having the delay value “A” has such a configuration that an operation element 162 having the predetermined delay value “ΔT” is added to a group of logic operation elements 161 having the delay value “B”. Therefore, the above-mentioned delay value “ΔT” is the delay value (delay time) of at least one logic operation element. With a configuration like this, the difference between the delay values of the logic circuits 141 and 142 can be reduced to the lowest limit. Therefore, the logic circuit 122 can be divided into two logic circuits 141 and 142 having roughly the same delay value. Note that although the logic operation element having the predetermined delay value “ΔT” is represented as an inverter circuit in FIG. 3, it may be other logic operation elements. However, it is desirable to select a logic operation element having a delay time as small as possible.

### Second Exemplary Embodiment

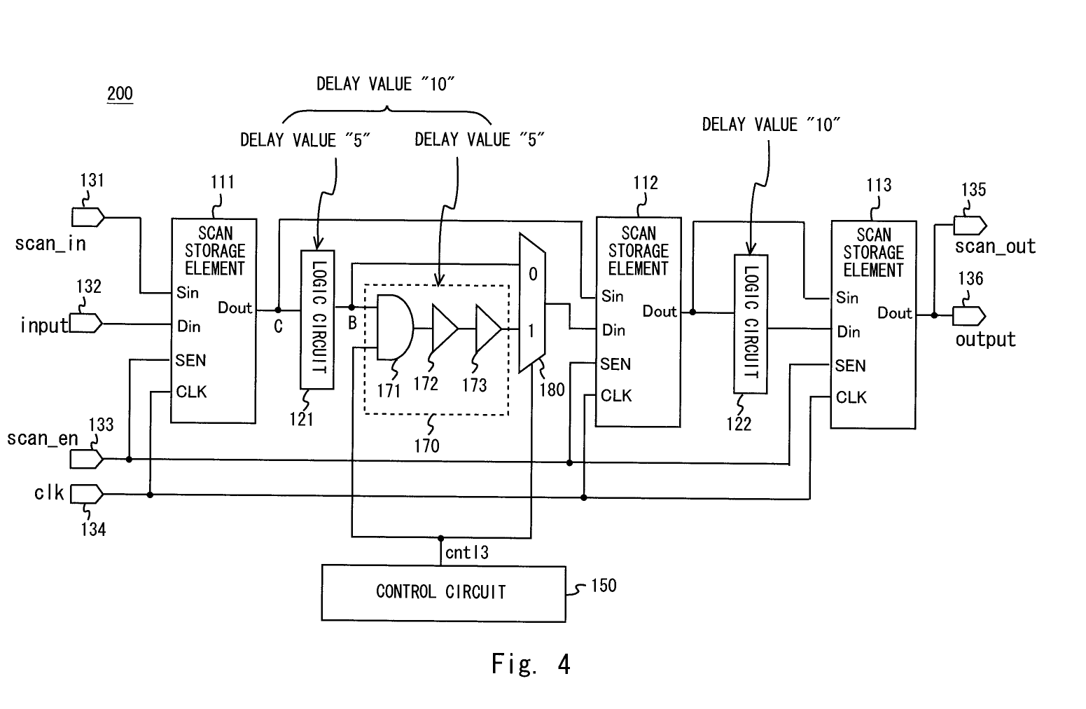

A second specific exemplary embodiment to which the present invention is applied is explained hereinafter with reference to the drawings. FIG. 4 shows an example of a configuration of a semiconductor integrated circuit 200 in accordance with this second exemplary embodiment of the present invention. Assume that in this second exemplary embodiment, a scan test circuit is formed from combinational circuits (logic circuits) and sequential circuits such as flip-flops to implement desired functions as in the case of the first exemplary embodiment. Assume also that the semiconductor integrated circuit 200 illustrated in the drawings represents a configuration in a scan test circuit. Note that structures denoted by the same signs as those of FIG. 1 represent the same or similar structures to those of FIG. 1. Therefore, the explanation of portions having similar structures to those of the first exemplary embodiment is omitted. A second exemplary embodiment of the present invention is different from the first exemplary embodiment in that a delay circuit is added to a logic circuit having a smaller delay value so that the delay value is made uniform with a logic circuit having a larger delay value. The following explanation is made with emphasis on features that are different from the first exemplary embodiment.

As shown in FIG. 4, the semiconductor integrated circuit 200 includes scan storage elements 111 to 113, logic circuits 121 and 122, an additional delay circuit 170, and a control circuit 150. Further, the semiconductor integrated circuit 200 also includes a scan data input terminal 131, a data input terminal 132, a scan enable signal input terminal 133, a clock signal input terminal 134, a scan data output terminal 135, and a data output terminal 136. Since all the terminals, all the storage elements, and the logic circuit 121 are similar to those of the first exemplary embodiment, explanation of their specific configurations is omitted. Further, unlike the first exemplary embodiment, the logic circuit 122 is not divided into a plurality of logic circuits, and has a delay value “10”.

The additional delay circuit 170 includes an AND circuit 171, and buffer circuits 172 and 173. The logic circuit 121 outputs a logic operation result according to an input data signal to a node B. One of the input terminals of the AND circuit 171 is connected to the node B. Further, a control signal cntl3 from the control circuit 150 is input to the other input terminal of the AND circuit 171. The AND circuit 171 calculates a logical multiplication of signals input to the one input terminal and the other input terminal, and outputs the operation result from the output terminal. Therefore, when the control signal cntl3 is at a Low level, it outputs a Low level regardless of the data signal applied to the node B. On the other hand, the control signal cntl3 is at a High level, it outputs a data signal having the same phase as the data signal applied to the node B from the output terminal.

The input terminal of the buffer circuit 172 is connected to the output terminal of the AND circuit 171, and the output terminal of the buffer circuit 172 is connected to the input terminal of the buffer circuit 173. The input terminal of the buffer circuit 173 is connected to the output terminal of the buffer circuit 172, and the output terminal of the buffer circuit 173 is connected to one of the input terminals of the selection circuit 180. The additional delay circuit 170 is configured so as to have a delay value “5” as the sum of the delay times of the AND circuit 171 and the buffer circuits 172 and 173 in regard to the input/output response. That is, the additional delay circuit 170 is configured so that the sum of the delay values of the logic circuit 121 and the additional delay circuit 170 becomes equals to the delay value of the logic circuit 122.

One of the input terminals of the selection circuit 180 is connected to the output of the buffer circuit 173 and the other input terminal is connected to the node B. Further, the output terminal of the selection circuit 180 is connected to the input terminal Din of the scan storage element 112. Further, a control signal cntl3 from the control circuit 150 is input to the control terminal of the selection circuit 180. It selects a data signal input to either the one input terminal or the other input terminal according to this control signal cntl3, and outputs the selected data signal from the output terminal. More specifically, when the control signal cntl3 is at a High level, it outputs a data signal input to the one input terminal from the output terminal. On the other hand, when the control signal cntl3 is at a Low level, it outputs a data signal input to the other input terminal from the output terminal. Therefore, the delay value of the circuit disposed between the scan storage elements 111 and 112 (second logic circuit) is selected from the delay value “5” of the logic circuit 121 or the total delay value “10” of the logic circuit 121 and the additional delay circuit 170 according to the control signal cntl3 of the control circuit 150. Note that the delay value of the circuit disposed between the scan storage elements 112 and 113 (first logic circuit) is the delay value “10” of the logic circuit 122.

Note that in the example shown in FIG. 4, a path that extends from the Dout terminal of the scan storage element 111, passes through the logic circuit 141, and connects to the Din terminal of the scan storage element 112 is defined as a first logic path. Further, a path that extends from the Dout terminal of the scan storage element 111, passes through the logic circuit 121 and the additional delay circuit 170, and connects to the Din terminal of the scan storage element 112 is defined as a second logic path. Further, a path that extends from the Dout terminal of the scan storage element 112, passes through the logic circuit 122, and connects to the Din terminal of the scan storage element 113 is defined as a third logic path.

Next, operations of the above-described semiconductor integrated circuit 200 are explained hereinafter. Note that since basic scan test operations were already explained above with reference to FIG. 15 and the like, their explanation is omitted here. Operations of the additional delay circuit 170 and the selection circuit 180 during a scan test, which are a characteristic part of this second exemplary embodiment, are explained hereinafter.

Firstly, the control signal cntl3 output from the control circuit 150 is brought to a High level during a scan test. In this state (hereinafter referred to as “third state”), the path that passes through both the logic circuit 121 and the additional delay circuit 170 is selected among the paths between the output terminal Dout of the scan storage element 111 and the input terminal Din of the scan storage element 112. Therefore, the output data signal of the scan storage element 111 is transmitted to the scan storage element 112 while the signal is delayed by the delay value “10”, i.e., the sum of the delay values of the logic circuit 121 and the additional delay circuit 170.

Note that the control signal cntl3 output from the control circuit 150 is kept at a Low level when the semiconductor integrated circuit 200 is in a normal operating state and when it is in the shift mode of a scan test state. In this case, the path that passes through only the logic circuit 121 is selected among the paths between the output terminal Dout of the scan storage element 111 and the input terminal Din of the scan storage element 112. Therefore, a data signal that is input to the input terminal Din of the scan storage element 112 is transmitted with the normal delay value of the logic circuit 121. Accordingly, even though the semiconductor integrated circuit 100 has a configuration in accordance with this second exemplary embodiment, it has no effect on operations in the normal operating state. Further, since a Low-level signal is input to the AND circuit 171, the buffer circuits 172 and 173 in the subsequent stage do not become active. Therefore, the electrical power consumed in the buffer circuits 172 and 173 can be reduced.

In the semiconductor integrated circuit 200 in accordance with this second exemplary embodiment, the additional delay circuit 170 is added to the logic circuit 121 so that it has the same delay value as that of the logic circuit 122, which is the critical path as shown in FIG. 4. Then, during the scan test, the test is carried out with a path that passes through both the logic circuit 121 and the additional delay circuit 170. The pulse cycle of the clock signal clk for use in a scan mode for this case is set in accordance with the delay value “10”. In this manner, as shown in a schematic diagram of FIG. 5, if the logic circuit 121 has some defect and thereby has an abnormal delay value of “8” instead of the normal delay value of “5”, the total delay value including the delay value of the additional delay circuit 170 becomes “13”. Since this abnormal delay value “13” is larger than the delay value “10”, a result indicating that the data measured by the scan test is different from the expected values is obtained. Therefore, similarly to the first exemplary embodiment, it becomes possible to detect a defect in the logic circuit 121 that cannot be detected in the circuit configuration of the semiconductor integrated circuit 1.

Further, it is necessary to carry out each scan test with a pass that passes through the respective one of logic circuits 141 and 142 in the first exemplary embodiment. Therefore, the scan test needs to be carried out twice. However, this second exemplary embodiment requires the scan test to be carried out only once. Therefore, it is possible to curtail the testing process, and thus providing a merit that the testing costs can be cut down. Further, in this second exemplary embodiment, the logic value to be input to the scan storage element 112 is not affected at all even when the path that passes through both the logic circuit 121 and the additional delay circuit 170 is used. Therefore, in addition to the scan test, an actual operation test can be also carried out while the additional delay circuit 170 is added to the logic circuit 121. Further, if the result of that actual operation test is different from the expected values, it can be determined that the logic circuit 121 has a defect.

Note that in the semiconductor integrated circuit 200 shown in FIG. 4, the additional delay circuit 170 and the selection circuit 180 are connected between the node B and the scan storage element 112. However, the additional delay circuit 170 and the selection circuit 180 can be connected between the node C and the logic circuit 121.

### Third Exemplary Embodiment

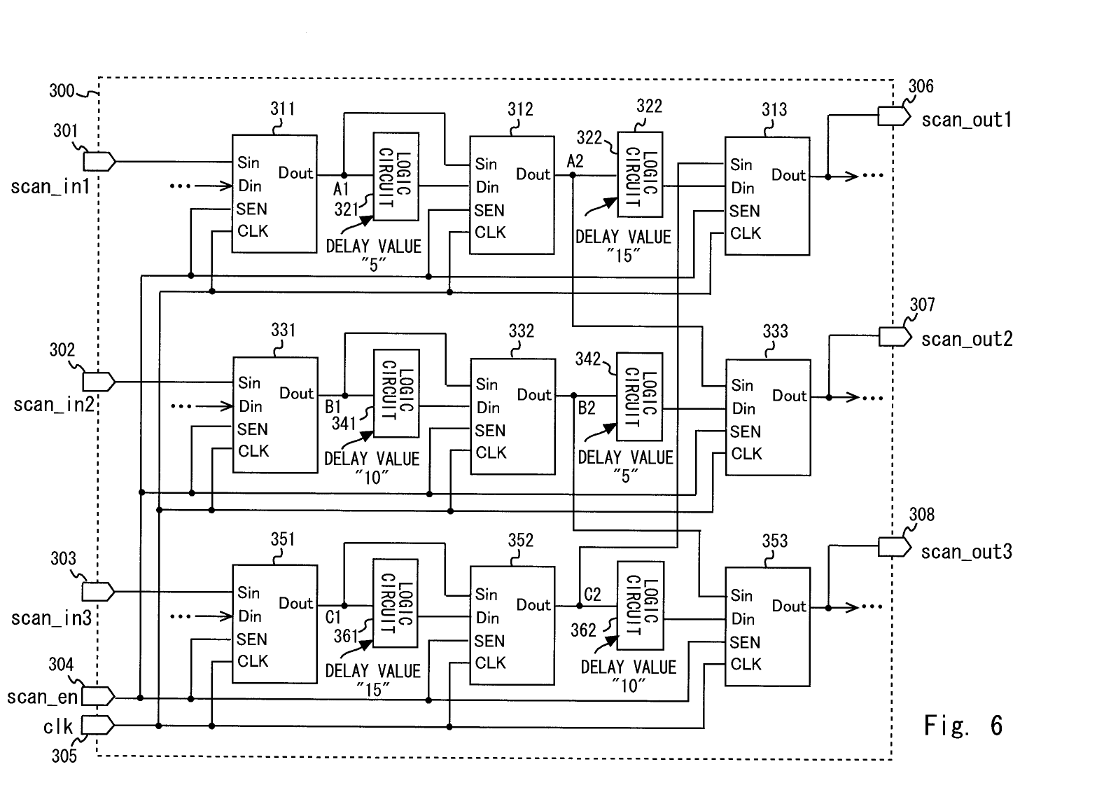

A third specific exemplary embodiment to which the present invention is applied is explained hereinafter with reference to the drawings. Note that a semiconductor integrated circuit in accordance with this third exemplary embodiment of the present invention is configured to have multi scan chains. FIG. 6 shows an example of a configuration of a semiconductor integrated circuit 300 in accordance with this third exemplary embodiment of the present invention.

As shown in FIG. 6, the semiconductor integrated circuit 300 includes scan storage elements 311-313, 331-333 and 351-353, and logic circuits 321, 322, 341, 342, 361 and 362. Further, the semiconductor integrated circuit 300 also includes scan data input terminals 301, 302 and 303, scan data output terminal 306, 307 and 308, a scan enable signal input terminal 304, and a clock signal input terminal 305.

Each of the scan storage elements 311-313, 331-333 and 351-353 has a similar configuration to that of the scan storage elements 111 to 113 in accordance with the first exemplary embodiment. Therefore, explanation of their details such as operations is omitted. Further, a clock signal clk that is supplied from the clock signal input terminal 305 is input to the terminal CLK of each of the scan storage elements 311-313, 331-333 and 351-353. Further, a scan enable signal scan_en that is supplied from the scan enable signal input terminal 304 is input to the terminal SEN of each of the scan storage elements 311-313, 331-333 and 351-353. The logic circuits 321 and 342 each have a delay value “5”. The logic circuits 341 and 362 each have a delay value “10”. The logic circuits 361 and 322 each have a delay value “15”.

The terminal Sin of the scan storage element 311 is connected to the scan data input terminal 301, and the terminal Dout is connected to a node A1. Further, a data signal output from the preceding logic circuit is input to the terminal Din of the scan storage element 311. The logic circuit 321 receives a data signal from the node A1, and outputs a logic operation result for the input to the terminal Din of the scan storage element 312.

The terminal Sin of the scan storage element 312 is connected to the node A1, and the terminal Dout is connected to a node A2. Further, a data signal output from the logic circuit 321 is input to the terminal Din of the scan storage element 312. The logic circuit 322 receives a data signal from the node A2, and outputs a logic operation result for the input to the terminal Din of the scan storage element 313.

The terminal Sin of the scan storage element 313 is connected to the node C2, and the terminal Dout is connected to the scan data output terminal 306 and a logic circuit in the subsequent stage. Further, a data signal output from the logic circuit 322 is input to the terminal Din of the scan storage element 313.

The terminal Sin of the scan storage element 331 is connected to the scan data input terminal 302, and the terminal Dout is connected to a node B1. Further, a data signal output from the preceding logic circuit is input to the terminal Din of the scan storage element 331. The logic circuit 341 receives a data signal from the node B1, and outputs a logic operation result for the input to the terminal Din of the scan storage element 332.

The terminal Sin of the scan storage element 332 is connected to the node B1, and the terminal Dout is connected to a node B2. Further, a data signal output from the logic circuit 341 is input to the terminal Din of the scan storage element 332. The logic circuit 342 receives a data signal from the node B2, and outputs a logic operation result for the input to the terminal Din of the scan storage element 333.

The terminal Sin of the scan storage element 333 is connected to the node A2, and the terminal Dout is connected to the scan data output terminal 307 and a logic circuit in the subsequent stage. Further, a data signal output from the logic circuit 342 is input to the terminal Din of the scan storage element 333.

The terminal Sin of the scan storage element 351 is connected to the scan data input terminal 303, and the terminal Dout is connected to a node C1. Further, a data signal output from the preceding logic circuit is input to the terminal Din of the scan storage element 351. The logic circuit 361 receives a data signal from the node C1, and outputs a logic operation result for the input to the terminal Din of the scan storage element 352.

The terminal Sin of the scan storage element 352 is connected to the node C1, and the terminal Dout is connected to a node C2. Further, a data signal output from the logic circuit 361 is input to the terminal Din of the scan storage element 352. The logic circuit 362 receives a data signal from the node C2, and outputs a logic operation result for the input to the terminal Din of the scan storage element 353.

The terminal Sin of the scan storage element 353 is connected to the node B2, and the terminal Dout is connected to the scan data output terminal 308 and a logic circuit in the subsequent stage. Further, a data signal output from the logic circuit 362 is input to the terminal Din of the scan storage element 353.

With the above-described configuration, one scan chain (hereinafter referred to as “first scan chain”) is formed from the scan data input terminal 301, the scan storage elements 311, 312 and 333, and the scan data output terminal 307 in the above-described semiconductor integrated circuit 300. This first scan chain is formed with consideration given to the logic circuits 321 and 342 each having the delay value “5”.

Further, another scan chain (hereinafter referred to as “second scan chain”) is formed from the scan data input terminal 302, the scan storage elements 331, 322 and 353, and the scan data output terminal 308. This second scan chain is formed with consideration given to the logic circuits 341 and 362 each having the delay value “10”.

Further, another scan chain (hereinafter referred to as “third scan chain”) is formed from the scan data input terminal 303, the scan storage elements 351, 352 and 313, and the scan data output terminal 306. This third scan chain is formed with consideration given to the logic circuits 361 and 322 each having the delay value “15”.

Next, operations of the above-described semiconductor integrated circuit 300 are explained hereinafter. Note that since basic scan test operations were already explained above with reference to FIG. 15 and the like, their explanation is omitted here. Firstly, a scan test (hereinafter referred to as “first condition scan test”) is carried out while the pulse cycle of the clock signal clk for use in a scan mode is set for the delay value “15”.

By carrying out this first condition scan test, the scan storage elements 312 and 333 in the first scan chain store logic operation results of the logic circuits 321 and 342, respectively, each of which has the delay value “5”. Further, the scan storage elements 332 and 353 in the second scan chain store logic operation results of the logic circuits 341 and 362, respectively, each of which has the delay value “10”. Further, the scan storage elements 352 and 313 in the third scan chain store logic operation results of the logic circuits 361 and 322, respectively, each of which has the delay value “15”.

Then, after the test, scan data stored in the respective scan storage elements 351, 352 and 313 of the third scan chain is taken out from the scan data output terminal 306 and compared with the expected values. Note that similarly, scan data of the first and second scan chains is also taken out from the scan data output terminals 307 and 308 respectively. However, output data from the scan chains other than the third scan chain, on which attention is focused, is abandoned.

Next, another scan test (hereinafter referred to as “second condition scan test”) is carried out while the pulse cycle of the clock signal clk for use in a scan mode is set for the delay value “10”. By carrying out this second condition scan test, operation results of the logic circuits are stored in the respective scan storage elements of the first to third scan chains in a similar manner to that of the first condition scan test. Then, after the test, scan data stored in the respective scan storage elements 331, 332 and 353 of the second scan chain is taken out from the scan data output terminal 308 and compared with the expected values. Further, output data from the scan chains other than the second scan chain, on which attention is focused, is abandoned as in the case of the first condition scan test.

Next, another scan test (hereinafter referred to as “third condition scan test”) is carried out while the pulse cycle of the clock signal clk for use in a scan mode is set for the delay value “5”. By carrying out this third condition scan test, operation results of the logic circuits are stored in the respective scan storage elements of the first to third scan chains as in the case of the first and second condition scan tests. Then, after the test, scan data stored in the respective scan storage elements 311, 312 and 333 of the first scan chain is taken out from the scan data output terminal 307 and compared with the expected values. Further, output data from the scan chains other than the first scan chain, on which attention is focused, is abandoned as in the case of the first and second condition scan tests.

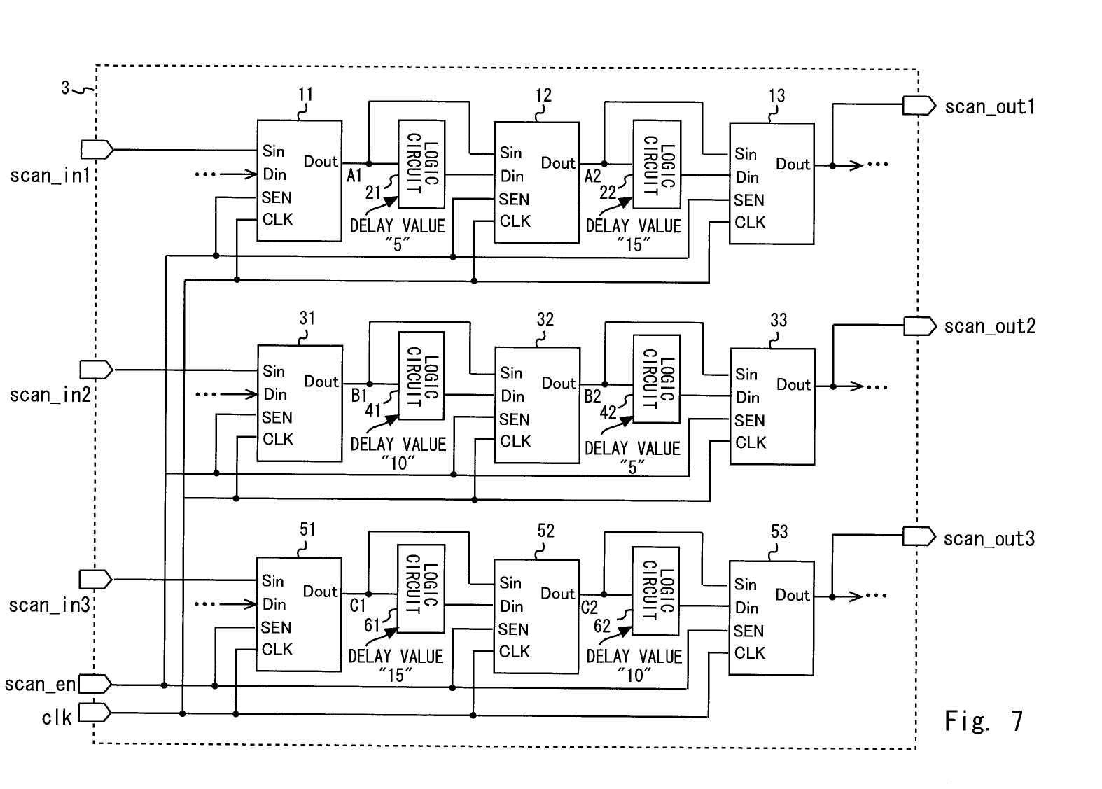

FIG. 7 shows a configuration of a semiconductor integrated circuit 3 in related art. The semiconductor integrated circuit 3 includes scan storage elements 311-313, 331-333 and 351-353, and logic circuits 321, 322, 341, 342, 361 and 362. Further, the semiconductor integrated circuit 3 also includes scan data input terminals 301, 302 and 303, scan data output terminal 306, 307 and 308, a scan enable signal input terminal 304, and a clock signal input terminal 305. Note that structures denoted by the same signs as those of FIG. 6 represent the same or similar structures to those of FIG. 6.

As can be seen from FIG. 7, the semiconductor integrated circuit 3 includes similar components to those of the semiconductor integrated circuit 300. However, part of the connection relation between the components is different. Specifically, they are different in that: the terminal Sin of the scan storage element 313 is connected to the node A2; the terminal Sin of the scan storage element 333 is connected to the node B2; and the terminal Sin of the scan storage element 353 is connected to the node C2. Therefore, one scan chain is formed from the scan data input terminal 301, the scan storage elements 311, 312 and 313, and the scan data output terminal 306. Similarly, another scan chain is formed from the scan data input terminal 302, the scan storage elements 331, 332 and 333, and the scan data output terminal 307. Further, another scan chain is formed from the scan data input terminal 303, the scan storage elements 351, 352 and 353, and the scan data output terminal 308. Unlike the semiconductor integrated circuit 300 in accordance with this third exemplary embodiment, these scan chains are formed without considering the delay values of the logic circuits.

Therefore, even if the logic circuit 321 has some defect and thereby has an abnormal delay value of “8” instead of the normal delay value of “5”, this defect is hidden due to the effect of the logic circuit having the delay value “15” and thereby cannot be detected by the scan test. That is, the scan test must be carried out while the pulse cycle of the clock signal clk for use in a scan mode is set for a delay value “15” to conform to the critical path, i.e., the logic circuits 322 and 361 having the delay value “15”.

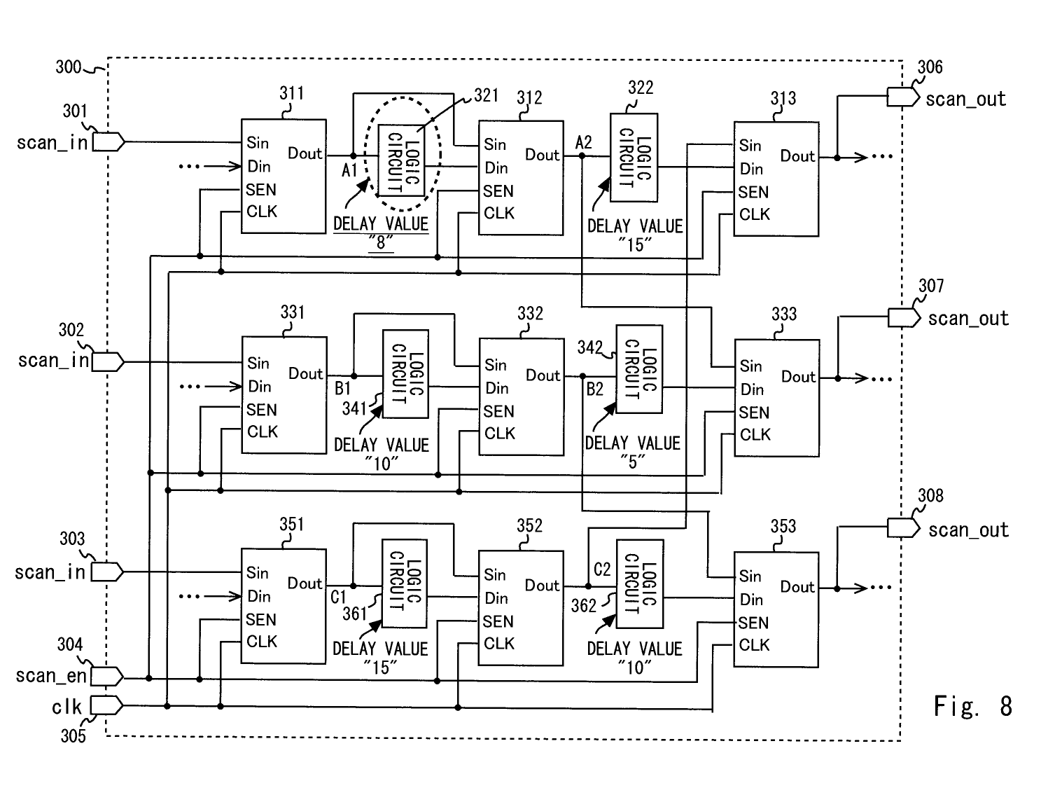

By contrast, in the semiconductor integrated circuit 300 in accordance with this third exemplary embodiment, if the logic circuit 321, for example, has a defect as shown in FIG. 8, this defect can be detected by the third condition scan test. In this manner, the semiconductor integrated circuit 300 in accordance with this third exemplary embodiment can detect a defect, which cannot be detected in the semiconductor integrated circuit 3 in related art, by configuring the wiring pattern of scan chains with consideration given to the delay values of the respective logic circuits.

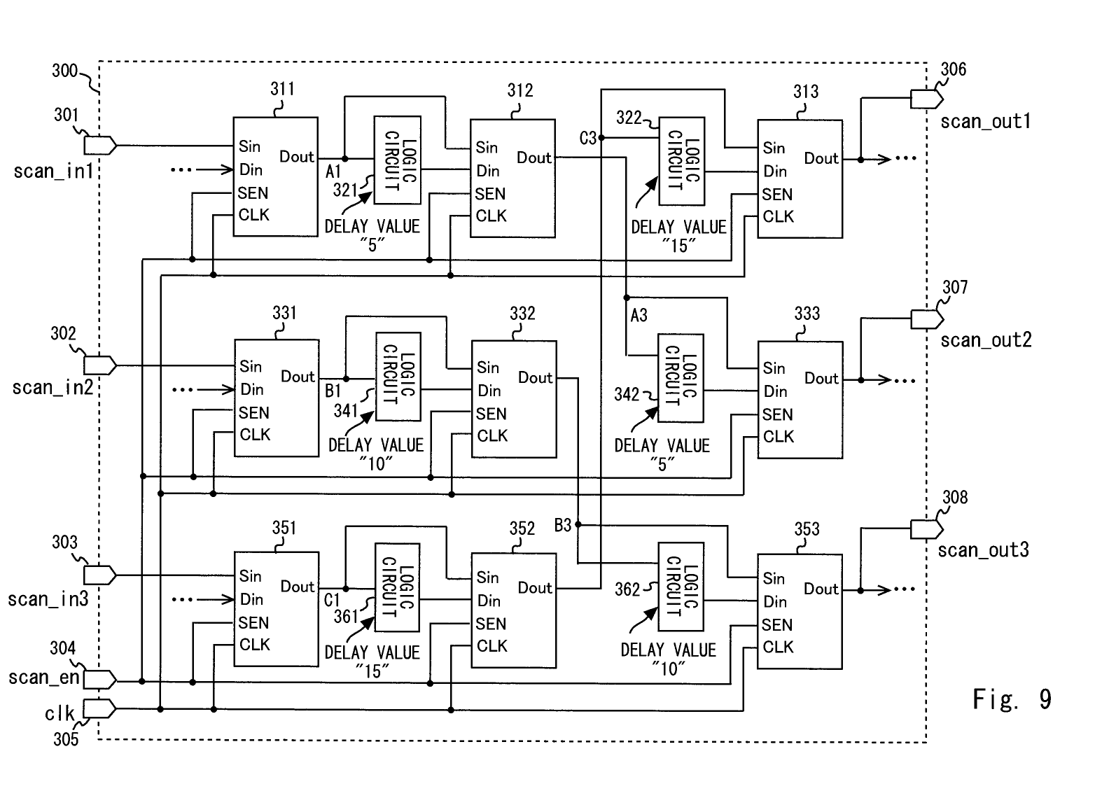

FIG. 9 shows another configuration example of a semiconductor integrated circuit 300 in accordance with this third exemplary embodiment of the present invention. It is different from the configuration of FIG. 6 in that part of the connection relation between the components is different. These differences are described hereinafter. Firstly, the terminals Dout of the scan storage elements 312, 332 and 352 are connected to nodes A3, B3 and C3 respectively. The logic circuits 322, 342 and 362 are connected between the nodes C3, A3 and B3, and the terminals Din of the scan storage elements 313, 333 and 353 respectively. Further, the terminals Sin of the scan storage elements 313, 333 and 353 are connected to nodes C3, A3 and B3 respectively.

With a configuration like this, initial values that are to be stored in the respective scan storage elements during a scan test can be set while attention is focused only on the respective scan chains. That is, there is no need to create a test pattern that takes test results among different scan chains into consideration. In this way, it provides advantages that the efficiency in the test pattern creation improves and that the detection rate also improves.

### Fourth Exemplary Embodiment

A fourth specific exemplary embodiment to which the present invention is applied is explained hereinafter with reference to the drawings. In this fourth exemplary embodiment, a method of designing a semiconductor integrated circuit 100, 200 or 300 in accordance with the above-described first to third exemplary embodiments is described. This designing of a circuit is performed by using a computer such as a PC (personal computer).

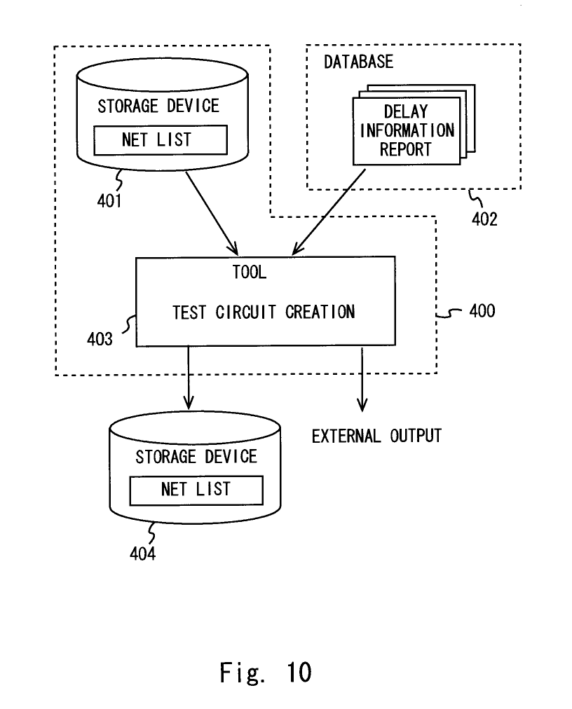

FIG. 10 is a schematic diagram for explaining a method of designing a semiconductor integrated circuit in accordance with this fourth exemplary embodiment of the present invention. As shown in FIG. 10, a net list of a semiconductor integrated circuit 100, 200 or 300 is created so that it has desired functions, and that circuit information is stored in a storage device 400 such as a memory and an HDD (hard disk drive) of a computer. A net list on which a test circuit for a scan test is reflected (hereinafter referred to as “net list on which a test circuit is reflected”) is created from the stored circuit information and a delay information report of combinational circuits (logic circuits) that is contained in circuit information created in a database 402 or the like as a library by a test circuit creation tool 403 that is operated in a computer 400.

For example, in the case of a semiconductor integrated circuit 100 in accordance with the first exemplary embodiment, the logic circuit 122 having the delay value “10” is divided into the logic circuits 141 and 142 each having a delay value “5” by implementing a scan chain connection. Then, selection circuits 143 and 144 are connected. In the case of a semiconductor integrated circuit 200 in accordance with the second exemplary embodiment, an additional delay circuit 170 having a delay value “5” is added to the logic circuit 121 having a delay value “5” by implementing a scan chain connection. Then, a selection circuit 180 is connected. In the case of a semiconductor integrated circuit 300 in accordance with the third exemplary embodiment, a scan chain with consideration given to a plurality of logic circuits each having a delay value “5”, a scan chain with consideration given to a plurality of logic circuits each having a delay value “10”, and a scan chain with consideration given to a plurality of logic circuits each having a delay value “15” are implemented. Then, the net list on which the test circuit is reflected is stored again in a storage device 404 such as a memory and an HDD, or is externally output. Note that the same storage device may be used as both the storage devices 404 and 401.

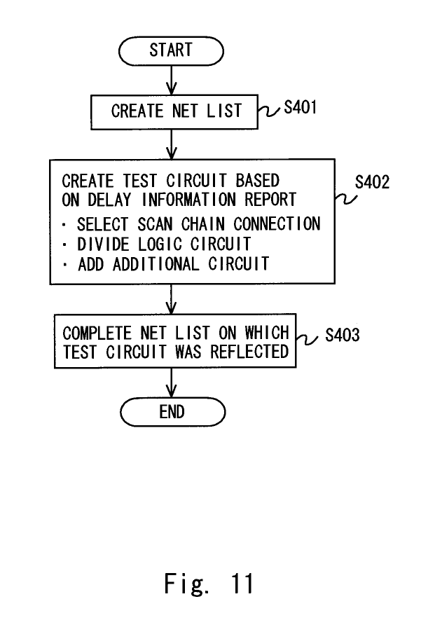

FIG. 11 is a flowchart of a method of designing a semiconductor integrated circuit in accordance with this fourth exemplary embodiment of the present invention. Firstly, a net list of a semiconductor integrated circuit 100, 200 or 300 is created such that it has desired functions (S401). Next, a division(s) of a logic circuit(s) like the semiconductor integrated circuit 100, an addition(s) of an additional delay circuit(s) like the semiconductor integrated circuit 200, and/or a construction of a scan chain(s) with consideration given to delay values of logic circuits like the semiconductor integrated circuit 300 are implemented while it is linked to a delay information report of combinational circuits (logic circuits) contained in circuit information created in the step S401, and thereby a net list on which a test circuit was reflected is created (S402). The completed test circuit on which the test circuit was reflected is stored in a storage device (S403).

As described above, a method of designing a semiconductor integrated circuit in accordance with this fourth exemplary embodiment makes it possible to create, based on information from the delay information report, a net list on which a test circuit is reflected so that a scan test(s) can be carried out for logic circuits having roughly the same delay value(s).

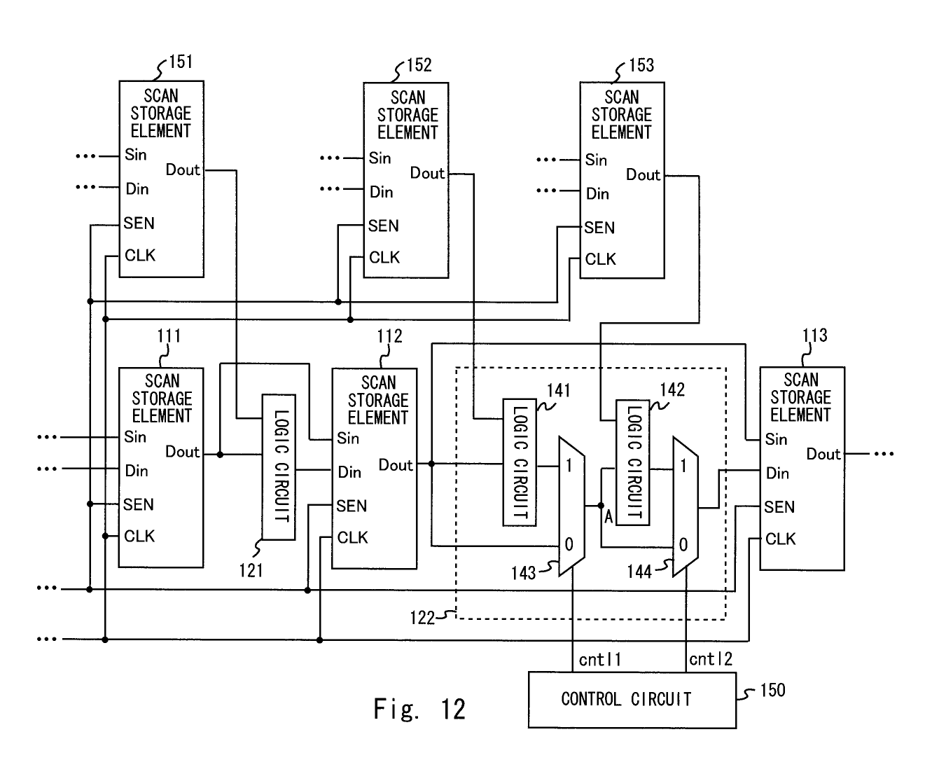

Note that the present invention is not limited to the above-described exemplary embodiments, and modifications can be made as appropriate without departing from the spirit and the scope of the present invention. For example, features of the first to third exemplary embodiments can be combined in a single semiconductor integrated circuit. Further, as shown in FIG. 12, scan storage elements 151 to 153 other than the scan storage elements 111 and 112 may be connected to the logic circuits 141 and 142 of the logic circuits 121 and 122. That is, multi-input type logic circuits having two or more inputs in addition to single-input logic circuits may be also tested by the scan test. Note that although the explanation of FIG. 12 is made based on the first exemplary embodiment, it may be also applied to the second and third exemplary embodiments.

The first to fourth exemplary embodiments can be combined as desirable by one of ordinary skill in the art.

(Further exemplary embodiment) A method of testing a semiconductor integrated circuit, the semiconductor integrated circuit including: first and second scan storage elements forming a scan chain; and first and second logic circuits connected to inputs of the first and second scan storage elements respectively, wherein the first logic circuit includes a first logic path and a second logic path to an input of the first scan storage element, and the second logic circuit includes a third logic path to an input of the second scan storage element, the third logic path having a delay difference that is larger than or equal to a predetermined range with respect to the first logic path and within a predetermined range with respect to the second logic path, and wherein the semiconductor integrated circuit is operated with the first logic path in a normal state and operated with second logic path during a scan test.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor integrated circuit comprising:
first and second scan storage elements forming a scan chain; and
first and second logic circuits connected to inputs of the first and second scan storage elements respectively,
wherein the first logic circuit comprises a first logic path and a second logic path to an input of the first scan storage element,
the first logic path becomes active in a normal state and has a delay difference larger than or equal to a predetermined range with respect to a third logic path possessed by the second logic circuit, the third logic path extending to an input of the second scan storage element, and
the second logic path becomes active during a scan test and has a delay difference within a predetermined range with respect to the third logic path.

2. The semiconductor integrated circuit according to claim 1, wherein
the second logic is divided into third and fourth logic circuits,
the first logic path is formed from the third and fourth logic circuits, and
the second logic path is formed from the third or fourth logic circuit.

3. The semiconductor integrated circuit according to claim 2, wherein first logic circuit is divided into the third and fourth logic circuits so that a delay difference between the third and fourth logic circuits falls within the predetermined range.

4. The semiconductor integrated circuit according to claim 3, further comprising:
a control circuit; and
first and second selection circuits controlled by the control circuit,
wherein one input of the first selection circuit is connected to the third logic circuit and another input of the first selection circuit is connected to a scan storage element in a preceding stage, and
one input of the second selection circuit is connected to the fourth logic circuit and another input of the second selection circuit is connected to an output of the first selection circuit, and
wherein, during the scan test, the control circuit causes the first selection circuit to select and output the one input and causes the second selection circuit to select and output the another input in a first state, and
the control circuit causes the first selection circuit to select and output the another input and causes the second selection circuit to select and output the one input in a second state.

5. The semiconductor integrated circuit according to claim 4, wherein the control circuit causes the first selection circuit to select and output the another input and causes the second selection circuit to select and output the another input in the normal state.

6. The semiconductor integrated circuit according to claim 1, wherein
the first logic circuit includes a fifth logic circuit and a delay circuit,
the first logic path is formed from the fifth logic circuit, and
the second logic path is formed from the fifth logic circuit and the delay circuit.

7. The semiconductor integrated circuit according to claim 6, further comprising:
a control circuit; and
a third selection circuit connected between a scan storage element in a preceding stage and the first storage element, the third selection circuit being controlled by the control circuit, and
wherein one input of the third selection circuit is connected to a path including the delay circuit and another input of the third selection circuit is connected to a path not including the delay circuit, and
wherein the control circuit causes the third selection circuit to select and output the one input in a normal state, and
the control circuit causes the third selection circuit to select and output the another input during a scan test.

8. The semiconductor integrated circuit according to claim 1, wherein the delay difference within the predetermined range corresponds to a delay period of at least one logic element.

9. A method of designing a semiconductor integrated circuit by using a computer, the semiconductor integrated circuit comprising a plurality of logic circuits each of which receives an output signal from a flip-flop connected in a preceding stage and outputs its operation result to a flip-flop in a subsequent stage, the method comprising:
creating a net list containing circuit information of first and second logic circuits among the plurality of the logic circuits, a first flip-flop that receives an output of the first logic circuit, and a second flip-flop that receives an output of the second logic circuit; and
referring to the net list and a delay information report containing information of delays of the first and second logic circuits, and when a delay difference between the first and second logic circuits falls within a predetermined range, connecting the first and second flip-flops in a scan-chain connection.

10. A method of designing a semiconductor integrated circuit by using a computer, the semiconductor integrated circuit comprising a plurality of logic circuits each of which receives an output signal from a flip-flop connected in a preceding stage and outputs its operation result to a flip-flop in a subsequent stage, the method comprising:
creating a net list containing circuit information of first and second logic circuits among the plurality of the logic circuits, a first flip-flop that receives an output of the first logic circuit, and a second flip-flop that receives an output of the second logic circuit;
configuring at least one of the first and second logic circuits such that a division of a logic circuit or an addition of a delay circuit is possible in order to bring a delay difference between the first and second logic circuits within a predetermined range during a scan test by referring to the net list and a delay information report containing information of delays of the first and second logic circuits; and
connecting the first and second flip-flops in a scan-chain connection.

11. The method of designing a semiconductor integrated circuit by using a computer according to claim 10, wherein
when a delay of the first logic circuit is larger than a delay of the second logic circuit, the first logic circuit is divided into third and fourth logic circuits, and
the third and fourth logic circuits are configured such that a delay difference between the third and fourth logic circuits falls within the predetermined range.

12. The method of designing a semiconductor integrated circuit by using a computer according to claim 11, wherein a scan test is performed on the third logic circuit in a first state and is performed on the fourth logic circuit in a second state.

13. The method of designing a semiconductor integrated circuit by using a computer according to claim 10, wherein when a delay of the first logic circuit is smaller than a delay of the second logic circuit, a delay circuit having a predetermined delay value is connected to the first logic circuit so that a delay of the first logic circuit become substantially equal to a delay of the second logic circuit.
